(19) United States
(12) Patent Application Publication
(10) Pub. No.: US 2010/0321083 A1
(43) Pub. Date: Dec. 23, 2010

(54) Voltage Level Translating Circuit

(75) Inventors: David J. Chen, Endwell, NY (US); William F. Lawson, Vestal, NY (US); David W. Mann, Endwell, NY (US)

Correspondence Address: IBM CORPORATION;ROCHESTER IP LAW DEPT. 917, 3605 HIGHWAY 52 NORTH, ROCHESTER, MN, 55901-7829, US

(73) Assignee: INTERNATIONAL BUSINESS MACHINES CORPORATION, Armonk, NY (US)

(21) Appl. No.: 12/488,767

(22) Filed: Jun. 22, 2009

(51) Int. Cl. H03L 5/00; H01S 4/00

(52) U.S. Cl. 327/333; 29/592.1

(57) ABSTRACT

A voltage level translating circuit that allows low voltage signals to be translated to higher voltages, a design structure utilized in the design, manufacture, and/or testing of the voltage level translating circuit, and a method of manufacturing the voltage level translating circuit are described. The translating circuit utilizes two different voltage domains. The high voltage rail of the low voltage domain acts as the ground of the high voltage domain. The translating circuit also utilizes a voltage buffer electrically connected to the high voltage domain and to the low voltage domain to prevent the circuit devices in either domain from seeing too high of a voltage. The translating circuit allows the circuits after the translating circuit to work with signals utilizing the high voltage rail of the high voltage domain.

### BACKGROUND OF THE INVENTION

1. Field of the Invention

Embodiments of this invention relate generally to field of computer processing and more specifically relate to a voltage level translating circuit that allows low voltage signals to be translated to higher voltages, a design structure utilized in the design, manufacture, and/or testing of the voltage level translating circuit, and a method of manufacturing the voltage level translating circuit.

2. Description of the Related Art

As computer processing designs move to smaller technology nodes, the voltage that may be supported by circuit elements in the design also decrease. However, in some operating conditions these circuit elements may need to function in higher voltage environments (2.5V, 3.3V, 5V, etc.). The voltage level translating circuit described herein allows signals from the core domain (VDD=/<1.8V) to be translated to higher voltages even though the allowable voltage on these circuit elements is limited to levels lower than the higher voltage.

### SUMMARY OF THE INVENTION

A voltage level translating circuit utilizes a high voltage domain and a low voltage domain. The high voltage rail of the low voltage domain acts as the ground of the high voltage domain. The translating circuit also utilizes a voltage buffer that is electrically connected to the high voltage domain and to the low voltage domain to prevent the circuit devices in either domain from seeing too high of a voltage. The translating circuit resultantly allows the circuits after the translating circuit to utilize the voltage of the high voltage rail of the high voltage domain.

In an embodiment of the present invention the voltage level translating circuit includes a voltage buffer connected to a low voltage domain and a high voltage domain. The high voltage of the low voltage domain serves as the low voltage of the high voltage domain.

In another embodiment of the present invention the low voltage domain further includes a first inverter having a first logical input and outputting either a first voltage or a second voltage, and a second inverter having a second logical input and outputting either the first voltage or the second voltage. The second logical input is the logical inverse of the first logical input. The second voltage is larger than the first voltage, and is the high voltage of the low voltage domain.

In another embodiment of the present invention the high voltage domain further includes a third inverter having a logical input either at the second voltage or a third voltage and a logical output either at the third voltage or the second voltage, a fourth inverter having a logical input either at the third voltage or the second voltage and a logical output either at the second voltage or the third voltage, and a buffer electrically connected to the third inverter and the fourth inverter and outputting either the second voltage or the third voltage. The third voltage is larger than the second voltage.

In another embodiment of the present invention the voltage buffer further includes a first voltage buffer portion having a constant logical input at the second voltage and a logical output substantially at either the first voltage or the third voltage, and a second voltage buffer portion having a constant logical input at the second voltage and a logical output substantially at either the third voltage or the first voltage.

In another embodiment of the present invention the first voltage buffer portion further includes a first n-type field effect transistor (NFET), and a first p-type field effect transistor (PFET). The gate of the first NFET and the gate of the first PFET are at the second voltage, the source of the first NFET is electrically connected to the output of the first inverter, and the drain of the first NFET and the drain of the first PFET are electrically connected.

In another embodiment of the present invention the second voltage buffer portion further includes a second NFET, and a second PFET. The gate of the second NFET and the gate of the second PFET are at the second voltage, the source of the second NFET is electrically connected to the output of the second inverter, and the drain of the second NFET and the drain of the second PFET are electrically connected.

In another embodiment of the present invention the source of the first PFET, the logical input of the third inverter, and the logical output of the fourth inverter are electrically connected. The source of the second PFET, the logical input of the fourth inverter, the logical output of the third inverter, and the logical input of the buffer are electrically connected.

In another embodiment of the present invention, a design structure embodied in a machine readable storage medium for designing, manufacturing, or testing a design includes the various some or all of the features included in the embodiments of the voltage level translating circuit described above. In another embodiment of the present invention the design structure includes a netlist that describes the voltage level translating circuit. In another embodiment the design structure resides on storage medium as a data format used for the exchange of layout data of integrated circuits. In another embodiment the design structure includes at least one of test data files, characterization data, verification data, or design specifications.

In another embodiment of the present invention a method of manufacturing the voltage level translating circuit includes electrically connecting the gate and the drain of a first NFET to the respective gate and drain of a first PFET, electrically connecting the gate and the drain of a second NFET to the respective gate and drain of a second PFET, electrically connecting the connected gates of the first NFET and of the first PFET to the connected gates of the second NFET and of the second PFET; electrically connecting the source of the first NFET to the output of a first inverter; electrically connecting the source of the second NFET to the output of a second inverter; electrically connecting the source of the first PFET to the input of a third inverter and to the output of a fourth inverter; electrically connecting the source of the second PFET to the output of the third inverter and to the input of the fourth inverter, and electrically connecting the output of the third inverter to the input of a buffer.

In other embodiments the method of manufacturing the voltage level translating circuit may include the following features: The first inverter is configured to utilize a first logical input and is configured to output either a first voltage or a second voltage. The second inverter is configured to utilize the inverse of the first logical input as its input signal and is configured to output either the second voltage or the first voltage. The third inverter is configured to utilize a logical input either at the second voltage or a third voltage and is configured to output a logical output either at the third voltage or the second voltage. The fourth inverter is configured to utilize a logical input either at the third voltage or the second voltage and is configured to output a logical output either at the second voltage or the third voltage. The buffer is configured to output a translated voltage. The first inverter and the second inverter are configured to operate in a low voltage domain. The third inverter, the fourth inverter, and the buffer are configured to operate in a high voltage domain. The first NFET, the first PFET, the second NFET, and the second PFET are configured to operate as a voltage buffer, and wherein the high voltage of the low voltage domain is the second voltage and is configured to also serve as a low voltage of the high voltage domain.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 depicts an exemplary computer system capable of supporting, or otherwise allowing the operation of, various embodiments of the present invention.

FIG. 2 depicts a translating circuit that allows low voltage signals to be translated to higher voltages, according to various embodiments of the present invention.

FIG. 3 depicts a flow chart of a method of manufacturing a translating circuit, according to an embodiment of the present invention.

FIG. 4 depicts a block diagram of an exemplary design process utilized in semiconductor design, manufacturing, and or testing of a translating circuit, according to an embodiment of the present invention.

### DETAILED DESCRIPTION OF THE PREFERRED EMBODIMENTS

For a better understanding of the various embodiments of the present invention, together with other and further features and advantages thereof, reference is made to the following description, taken in conjunction with the accompanying drawings, and the scope of the invention asserted in the claims.

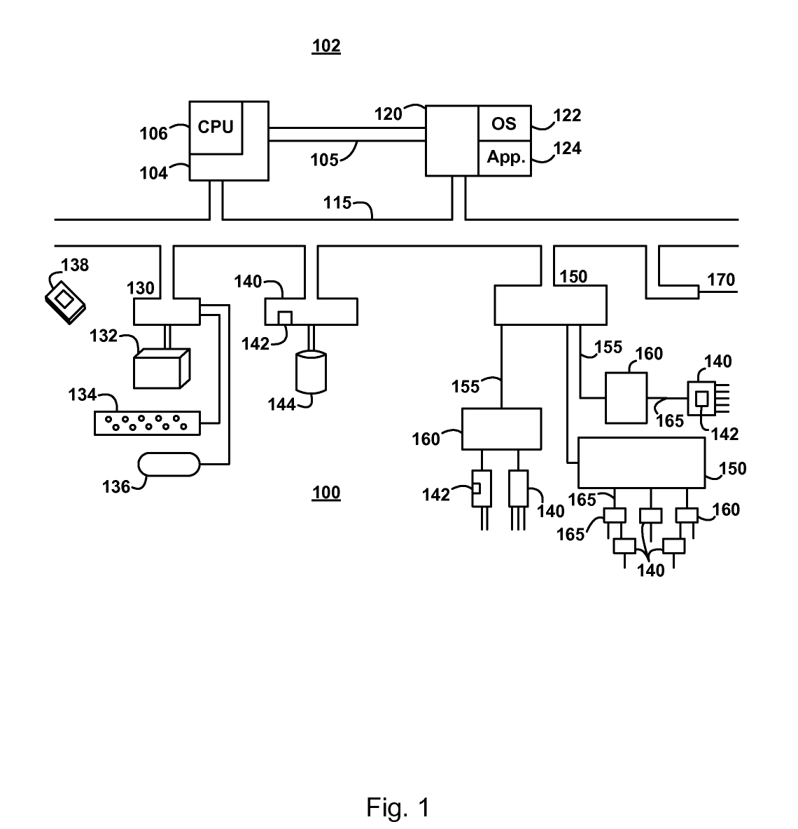

It will be readily understood that the components of the present invention, as generally described and illustrated in the Figures herein, may be arranged and designed in a wide variety of different configurations. Thus, the following more detailed description of the embodiments of the apparatus, system, and method of the present invention, as represented in FIGS. 1-4, is not intended to limit the scope of the invention, as claimed, but is merely representative of selected exemplary embodiments of the invention.

Reference throughout this specification to “one embodiment” or “an embodiment” (or the like) means that a particular feature, structure, or characteristic described in connection with the embodiment is included in at least one embodiment of the present invention. Thus, appearances of the phrases “in one embodiment” or “in an embodiment” in various places throughout this specification are not necessarily all referring to the same embodiment. In addition, features described in connection with a particular embodiment may be combined or excluded from other embodiments described herein.

Embodiments of the present invention are described below with reference to flowchart illustrations and/or block diagrams of methods, apparatus, design structure, and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer-readable medium that can direct a computer or other programmable data processing apparatus to function in a particular manner, such that the instructions stored in the computer-readable medium produce an article of manufacture including instruction means which implement the function/act specified in the flowchart and/or block diagram block or blocks.

Any combination of one or more computer usable or computer readable medium(s) may be utilized. The computer-usable or computer-readable medium may be, for example but not limited to, an electronic, magnetic, optical, electromagnetic, infrared, or semiconductor system, apparatus, device, or propagation medium. More specific examples (a non-exhaustive list) of the computer-readable medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CDROM), an optical storage device, a transmission media such as those supporting the Internet or an intranet, or a magnetic or other such storage device. Note that the computer-usable or computer-readable medium could even be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory. In the context of this document, a computer-usable or computer-readable medium may be any medium that can contain, store, communicate, propagate, or transport the program for use by or in connection with the instruction execution system, apparatus, or device. The computer-usable medium may include a propagated data signal with the computer-usable program code embodied therewith, either in baseband or as part of a carrier wave. The computer usable program code may be transmitted using any appropriate medium, including but not limited to wireless, wireline, optical fiber cable, RF, etc.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide processes for implementing the functions/acts specified in the flowchart and/or block diagram block or blocks. It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

FIG. 1 illustrates the components and an interconnection topology for an information handling system, typically a computer system 100 that utilizes the voltage level translating circuit. Computer system 100 may comprise a host 102 having a host processor complex 104 connected to a main memory 120 by an internal bus 105 and/or a host system bus 115. The host processor complex 104 has at least one general-purpose programmable processor unit (CPU) 106, executing program instructions stored in main memory 120. Although a single CPU 106 is shown in FIG. 1, it should be understood that many processor complexes 104 have multiple CPUs 106.

Main memory 120 may be physically included within the host processor complex 104 or connected to it via an internal bus system 105 or via a host system bus 115. Memory 120 is a random access semiconductor memory for storing data and programs; memory 120 is shown conceptually as a single monolithic entity but in many computer systems 100, memory is arranged as a hierarchy of caches and other memory devices. In some instances, a hierarchy of cache memories is associated with each CPU 106. Memory 120 includes operating system (OS) 122 and applications 124. Operating system 122 provides functions such as device drivers or interfaces, management of memory pages, management of multiple tasks, etc., as is known in the art. Applications 124 may include a server software application in which case network interface 170 may interact with a server software application 124 to enable computer system 100 to be a network server.

Host system bus 115 supports the transfer of data, commands, and other information between the host processor system 102 and any peripheral or external device attached to it, and any communication of data which may occur between the external devices independent of the host processor complex 102. While shown in simplified form as a single bus, the host system bus 115 may be structured as multiple buses which may be hierarchically arranged. Host system bus 115 is illustrated as being connected to a myriad of external or peripheral devices either through a connection hub 130, or through an adapter 140, or a multifunction adapter 150, or directly to a network 170. These peripheral devices may include a monitor or display 132, a keyboard 134, a mouse or other handheld device 136, and a printer 138. Display 132 may be a cathode-ray tube display, a flat panel display, or a touch panel, and other display technology. One or more adapters 140 may support keyboard 134 and pointing device 136 depicted as a mouse; it being understood that other forms of input devices could be used. The number and types of devices shown in FIG. 1 are illustrative only and ordinary users of computer systems now know that a great variety of connected devices exist; e.g., microphones, speakers, infrared remote controls, wireless, etc. Computer system 100 is not limited to those devices illustrated in FIG. 1.

The host system bus 115 is also shown connected to an adapter 140 illustrated here as an I/O adapter connected to an external memory device 144. External memory device 144 may be rotating magnetic disk storage, configuration. Adapter 140 includes adapter microcode or firmware and decision logic which may be embodied as a message processor 142. Adapters 140 may connect a wide variety of devices to the host computer system and to each other such as, but not limited to, tape drives, optical drives, printers, disk controllers, other bus adapters, PCI adapters, workstations using one or more protocols including, but not limited to, Token Ring, Gigabyte Ethernet, Ethernet, Fibre Channel, SSA, Fiber Channel Arbitrated Loop (FCAL), Serial SCSI, Ultra3 SCSI, Infiniband, FDDI, ATM, 1394, ESCON, wireless relays, Twinax, LAN connections, WAN connections, high performance graphics, etc.

The host system bus 115 may also be connected to a multifunction adapter 150 to which more I/O devices may be connected either directly, or through one or more bridge devices 160, or through another multifunction adapter 150 on either a primary bus 155 or a secondary bus 165.

Network interface 170 provides a physical connection for transmission of data to and from a network. The network may be Internet but could also be any smaller self-contained network such as an intranet, a WAN, a LAN, or other internal or external network using; e.g., telephone transmission lines, cable services, satellites, fiber optics, T1 lines, etc., and any various available technologies. Network interface 170 may comprise a modem connected to a telephone line through which an Internet access provider or on-line service provider is reached, but increasingly other higher bandwidth interfaces are implemented. For example, computer system 100 may be connected to another network server via a local area network using an Ethernet, Token Ring, or other protocol, or a second network server in turn being connected to the Internet. Alternatively, network interface 170 may be provided through cable television, fiber optics, satellites, wireless, or other connections.

Finally, computer system 100 need not be a computer at all, but may be a simpler appliance-like client device with less memory such as a network terminal, a thin client, a terminal-like devices, a voice response unit, etc. The convergence of computing, telecommunications and consumer electronics is causing a tremendous growth in the number and variety of pervasive mobile devices as clients. This mobile architecture enables the multitude of clients including laptops, sub-notebooks, handheld computers such as personal digital assistants and companion devices, and mobile appliances such as smartphones, pages, simple messaging devices and wearable devices. Thus when the computer system 100 is a mobile device, the adapters 140 and network interfaces 170 support a variety of multi-modal interfaces including traditional keyboard and mouse interfaces, small text screens, pen, touch screens, speech recognition, text-to-speech and other emerging technologies like wearable devices. Such special-purpose devices for accessing the world wide web, such as an Internet access box for a television set, or a portable wireless web accessing device, which can implement an adapter for the purpose of communicating data to/from another computer system are also intended to be within the scope of a computer system 100.

The computer system shown in FIG. 1 is intended to be a simplified representation, it being understood that many variations in system configuration are possible in addition to those specifically mentioned here. While computer system 100 could conceivably be a personal computer system, the computer system 100 may also be a larger computer system such as a general purpose server. Computer system 100 and its components are shown and described in FIG. 1 above as a more or less single, self-contained computer system. It is alternatively possible to use multiple computer systems, particularly multiple systems which share a single large database, each having a specialized task. References herein to a computer system 100 should be understood to include either a single computer or a collection of computer systems which provides access to a legacy application and to a network by which to connect to a client system.

The programs defining the functions of the various embodiments can be delivered to the computer system 100 and/or to the peripheral device for installation on a connected adapter via a variety of signal-bearing media, which include, but are not limited to: (a) information permanently stored on non-writable storage media; e.g., read only memory devices within either computer such as CD-ROM disks readable by CD-ROM; (b) alterable information stored on writable storage media; e.g., floppy disks within a diskette drive or a hard-disk drive; or (c) information conveyed to a computer by a telephone or a cable media network, including wireless communications. Such signal-bearing media, when carrying instructions that may be read by an adapter or a computer to direct the functions of the present invention, represent alternative embodiments.

In certain embodiments, when computer system 100 is programmed to perform particular functions pursuant to instructions from program software that implements the system and methods of this invention, such computer system 100 in effect becomes a special purpose computer particular to various methodology embodiments of this invention.

Design structures used in the design, manufacturing, or testing of the voltage translating circuit may be utilized to distribute a representation of the voltage translating circuit from or to computer system 100. The distribution may be on a distribution medium such as floppy disk or CD-ROM or may be on over a network such as the Internet using FTP, HTTP, or other suitable protocols. From there, the representation of the voltage translating circuit may be copied to a hard disk or a similar intermediate storage medium and later utilized.

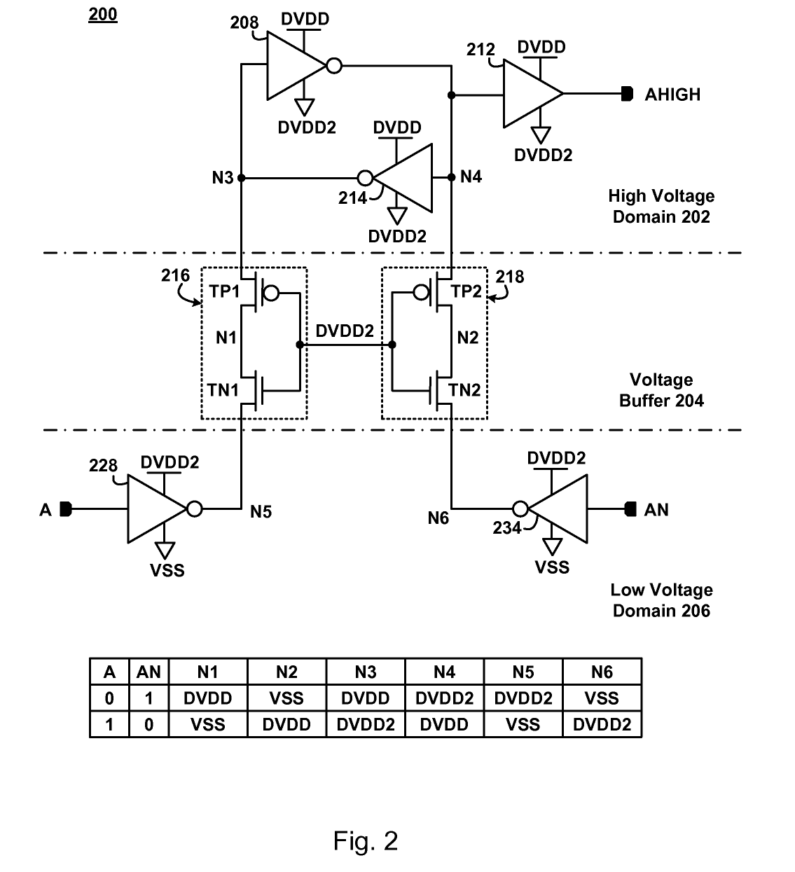

FIG. 2 depicts a translating circuit 200 that allows low voltage signals to be translated to higher voltages, according to various embodiments of the present invention. Translating circuit 200 comprises a high voltage domain 202, low voltage domain 206, and voltage buffer 204.

High voltage domain 202 comprises inverter 208, inverter 214, buffer 212, and high voltage output AHIGH. Low voltage domain 206 comprises inverter 228 and inverter 234. The input to inverter 228 is signal (A). The input to inverter 234 is the inverse of signal (A), or in other words signal (AN). Voltage buffer 204 comprises first voltage buffer portion 216 and second voltage buffer portion 218 which are shown in a more detailed transistor level view in FIG. 2. First voltage buffer portion 216 and Second voltage buffer portion 218 comprise two complimentary transistors in a CMOS configuration. First voltage buffer portion 216 comprises a n-type field effect transistor (NFET) TN1 and p-type field effect transistor (PFET) TP1. Second voltage buffer portion 218 comprises a NFET TN2 and a PFET TP2.

In an embodiment DVDD is greater than DVDD2 and DVDD2 is greater than VSS. In another embodiment a first voltage may be VSS, a second voltage may be DVDD2, and a third voltage may be DVDD. In a specific embodiment, DVDD may be for example 3.3V, DVDD2 may be 1.8V, and VSS may be 0V. In another embodiment a proper voltage bring-up sequence is to first bring up the voltage of DVDD2 prior to the voltage of DVDD.

The input to inverter 228 is signal (A). The output of inverter 228 is connected with the source of NFET TN1 at node N5. The gate of NFET TN1, the gate of PFET TP1, the gate of NFET TN2, and the gate of PFET TP2 are at a voltage of DVDD2. The drains of NFET TN1 and of PFET TP1 are electrically connected at node N1. The input to inverter 234 is signal (AN). The output of inverter 234 is connected with the source of NFET TN2 at node N6. The drains of NFET TN2 and of PFET TP2 are electrically connected at node N2.

The source of PFET TP1, the output of inverter 214, and the input of inverter 208 are electrically connected at node N3. The source of PFET TP2, the input of inverter 214, the output of inverter 208, and the input of buffer 212 are electrically connected at node N4. The output of buffer 212 is at voltage AHIGH, and may be a translated voltage used by other circuits (not shown).

The inverters utilized by translating circuit 200 (inverter 208, inverter 214, inverter 228, and inverter 234) are depicted as static CMOS inverters. In other embodiments, translating circuit 200 may be reconfigured to utilize a different inverter type or inverter configuration in place of these identified inverters.

The inverters in the high voltage domain 202 (inverter 208 and inverter 214) are weak, compared to the inverters in the low voltage domain, and may be overcome when the input signal (A) switches (i.e., A switches from “0” to “1” and AN switches from “1” to “0”). As a result, inverter 228 and inverter 234, through voltage buffer 204, are capable of setting the latch formed by inverters 208 and 214.

As an illustrative example, input signal (A) switches from “0” to “1”. The voltage at node N5 is pulled down to VSS. Because the gate of NFET TN1 is at DVDD2, the Gate Source Voltage (Vgs) of TN1 is above the gate-source threshold voltage, thus turning on NFET TN1. Resultantly, node N1 is pulled down to VSS.

Prior to input signal (A) switching to “1”, node N3 was at DVDD, N1 was at DVDD, the gate of PFET TP1 was at DVDD2 and therefore PFET TP1 was on. However, since N1 is now pulled down to VSS, the source of TP1 will start to get pulled down from DVDD and the voltage at node N3 is temporarily at DVDD2 plus a threshold voltage of TP1. After the latch made from inverter 208 and inverter 214 flips (input signal (A) switches to “1”) the voltage at N3 is pulled to DVDD2 by inverter 214. Because the gate of PFET TP1 is at DVDD2, PFET TP1 will turn off, preventing DVDD from affecting low voltage domain 206.

While the above is occurring on the left branch of translating circuit 200, the right branch of translating circuit 200 is doing the opposite. As (A) switches from “0” to “1”, (AN) switches from “1” to “0”, the voltage at node N6 will rise to DVDD2. The voltage at node N2 will rise as the voltage at node N6 rises until node N2 reaches one threshold voltage below DVDD2 (TN2 shuts off when node N2 reaches DVDD2). When the voltage on node N3 falls enough, the weak latch made from inverter 208 and inverter 214 will flip. The voltage at node N3 will fall to DVDD2 and the voltage at node N4 will rise to DVDD. With PFET TP2's gate at DVDD2, PFET TP2 will turn on, and the voltage at node N2 will rise to DVDD.

Therefore the voltage at node N3 (DVDD or DVDD2) logically follows the voltage at node N1 (DVDD2 or VSS), and the voltage at node N4 (DVDD2 or DVDD) logically follows the voltage at node N2 (VSS or DVDD2). In addition, the high voltage rail (DVDD2) of low voltage domain 206 acts as the ground (DVDD2) of the high voltage domain 202.

This topology of translating circuit 200 similarly operates when (A) switches from “1” to “0” and (AN) switches from “0” to “1”. A logic and voltage truth table is also shown in FIG. 2.

Once these voltages have settled into their DC states, the largest Vds across any single device in the translating circuit 200 is the greater of the value of DVDD2 or the value of the difference between DVDD and DVDD2. The circuit device type utilized in translating circuit 200 therefore should accommodate that Vds. Even though the devices can only tolerate voltages across its terminals of 1.8V (±the 1.8V rail tolerance), an I/O circuit that utilizes this level translator to drive the pull up PFET of a CMOS output stage, is able to provide interface signals driving full 3.3V CMOS levels.

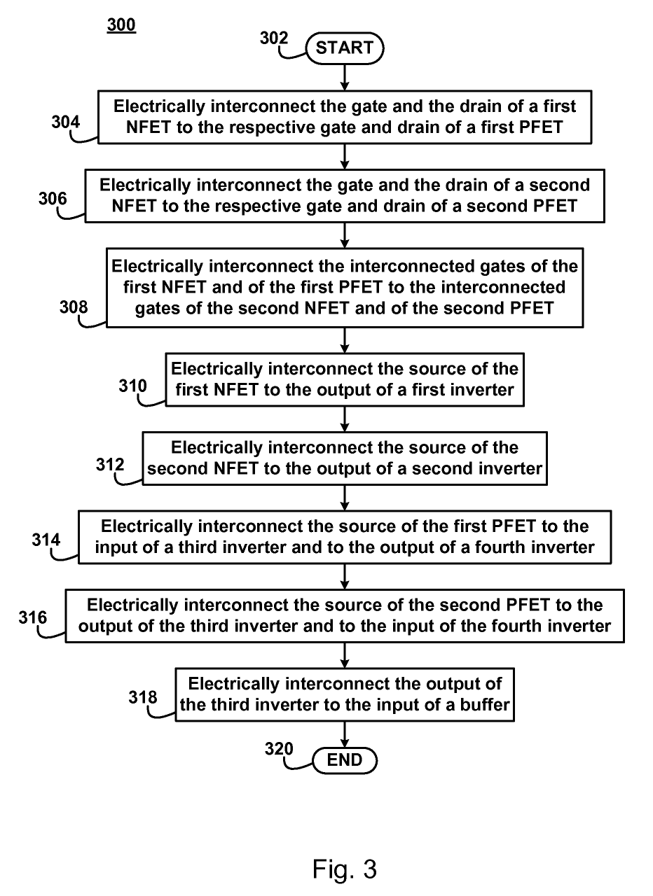

FIG. 3 depicts a flow chart of a method of manufacturing a translating circuit 200, according to an embodiment of the present invention. The method of manufacturing a translating circuit 300 starts at block 302. The gate and the drain of a first NFET are electrically connected to the respective gate and drain of a first PFET (block 304). The gate and the drain of a second NFET are electrically connected to the respective gate and drain of a second PFET (block 306). The connected gates of the first NFET and of the first PFET are electrically connected to the connected gates of the second NFET and of the second PFET (block 308). The source of the first NFET is electrically connected to the output of a first inverter (block 310). The source of the second NFET is electrically connected to the output of a second inverter (block 312). The source of the first PFET is electrically connected to the input of a third inverter and to the output of a fourth inverter (block 314). The source of the second PFET is electrically connected to the output of the third inverter and to the input of the fourth inverter (block 316). The output of the third inverter is electrically connected to the input of a buffer (block 318). The method of manufacturing a translating circuit 300 ends at block 320.

In other embodiments the method 300 of manufacturing the voltage level translating circuit 200 may include the following features: The first inverter is configured to utilize a first logical input and is configured to output either a first voltage or a second voltage. The second inverter is configured to utilize the inverse of the first logical input as its input signal and is configured to output either the second voltage or the first voltage. The third inverter is configured to utilize a logical input either at the second voltage or a third voltage and is configured to output a logical output either at the third voltage or the second voltage. The fourth inverter is configured to utilize a logical input either at the third voltage or the second voltage and is configured to output a logical output either at the second voltage or the third voltage. The buffer is configured to output a translated voltage that may be utilized by other circuits. The first inverter and the second inverter are configured to operate in a low voltage domain. The third inverter, the fourth inverter, and the buffer are configured to operate in a high voltage domain. The first NFET, the first PFET, the second NFET, and the second PFET are configured to operate as a voltage buffer.

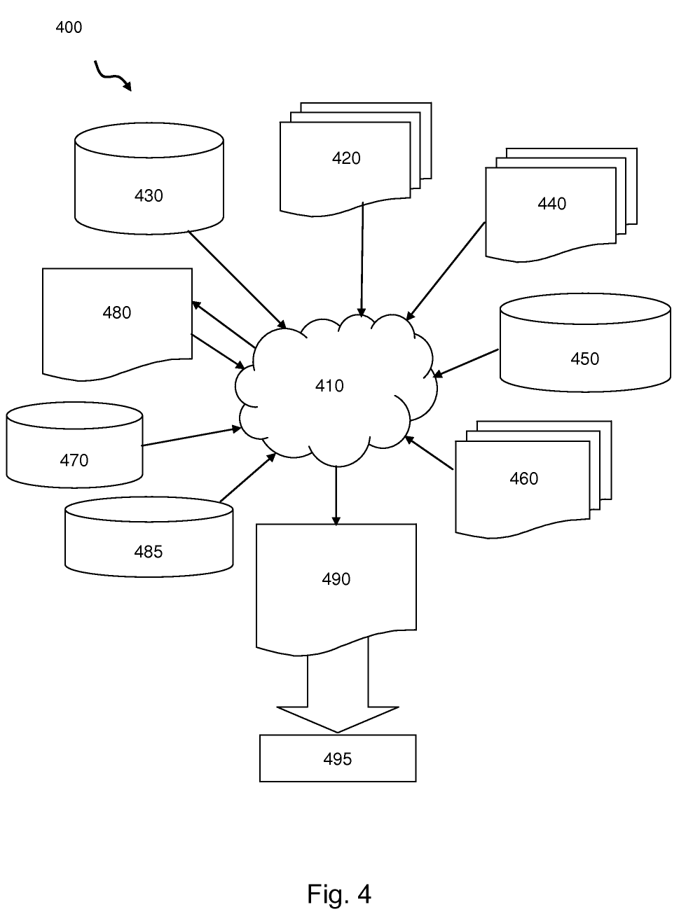

FIG. 4 depicts a block diagram of an exemplary design flow 400 utilized in the design and or manufacturing of translating circuit 200. Design flow 400 may vary depending on the type of IC being designed. For example, a design flow 400 for building an application specific IC (ASIC) may differ from a design flow 400 for designing a standard component. Design structure 420 is preferably an input to a design process 410 and may come from an IP provider, a core developer, or other design company or may be generated by the operator of the design flow, or from other sources. Design structure 420 comprises translating circuit 200 in the form of schematics or HDL, a hardware-description language (e.g., Verilog, VHDL, C, etc.). Design structure 420 may be contained on one or more machine readable medium. For example, design structure 420 may be a text file or a graphical representation of translating circuit 200. Design process 410 preferably synthesizes (or translates) translating circuit 200 into a netlist 480, where netlist 480 is, for example, a list of wires, transistors, logic gates, control circuits, I/O, models, etc., that describes the connections to other elements and circuits in an integrated circuit design and recorded on at least one machine readable medium. This may be an iterative process in which netlist 480 is resynthesized one or more times depending on design specifications and parameters for the circuit.

Design process 410 may include using a variety of inputs; for example, inputs from library elements 430 which may house a set of commonly used elements, circuits, and devices, including models, layouts, and symbolic representations, for a given manufacturing technology (e.g., different technology nodes, 32 nm, 45 nm, 90 nm, etc.), design specifications 440, characterization data 450, verification data 460, design rules 470, and test data files 485 (which may include test patterns and other testing information). Design process 410 may further include, for example, standard circuit design processes such as timing analysis, verification, design rule checking, place and route operations, etc. One of ordinary skill in the art of integrated circuit design can appreciate the extent of possible electronic design automation tools and applications used in design process 410 without deviating from the scope and spirit of the invention. The design structure of the invention is not limited to any specific design flow.

Design process 410 preferably translates an embodiment of the invention as shown in FIG. 2, along with any additional integrated circuit design or data, into a second design structure 490. Design structure 490 resides on a storage medium in a data format used for the exchange of layout data of integrated circuits (e.g., information stored in a GDSII (GDS2), GL1, OASIS, or any other suitable format for storing such design structures). Design structure 490 may comprise information such as, for example, test data files, design content files, manufacturing data, layout parameters, wires, levels of metal, vias, shapes, data for routing through the manufacturing line, and any other data required by a semiconductor manufacturer to produce an embodiment of the invention as shown in FIG. 2. Design structure 490 may then proceed to a stage 495 where, for example, design structure 490: proceeds to tape-out, is released to manufacturing, is released to a mask house, is sent to another design house, is sent back to the customer, etc.

It is to be understood that the present invention, in accordance with at least one present embodiment, includes elements that may be implemented on at least one electronic enclosure, such as general-purpose server running suitable software programs.

Although illustrative embodiments of the present invention have been described herein with reference to the accompanying drawings, it is to be understood that the invention is not limited to those precise embodiments, and that various other changes and modifications may be affected therein by one skilled in the art without departing from the scope or spirit of the invention.

The accompanying figures and this description depicted and described embodiments of the present invention, and features and components thereof. Those skilled in the art will appreciate that any particular program nomenclature used in this description was merely for convenience, and thus the invention should not be limited to use solely in any specific application identified and/or implied by such nomenclature. Thus, for example, the routines executed to implement the embodiments of the invention, whether implemented as part of an operating system or a specific application, component, program, module, object, or sequence of instructions could have been referred to as a “program”, “application”, “server”, or other meaningful nomenclature. Therefore, it is desired that the embodiments described herein be considered in all respects as illustrative, not restrictive, and that reference be made to the appended claims for determining the scope of the invention.

1. A voltage level translating circuit comprising:
a voltage buffer connected to a low voltage domain and a high voltage domain, wherein a high voltage of the low voltage domain serves as a low voltage of the high voltage domain;
wherein the low voltage domain further comprises:
a first inverter having a first logical input and outputting either a first voltage or a second voltage; and
a second inverter having a second logical input and outputting either the first voltage or the second voltage;
wherein the second logical input is the logical inverse of the first logical input, and wherein the second voltage is larger than the first voltage, and is the high voltage of the low voltage domain;
and wherein the high voltage domain comprises a latch formed by:
a third inverter having a logical input coupled to a first high voltage domain node and a logical output coupled to a second high voltage domain node, wherein said third inverter is a static CMOS inverter which drives said second voltage at the input of said third inverter to a third voltage at the output of said third inverter and drives said third voltage at the input of said third inverter to said second voltage at the output of said third inverter, and
a fourth inverter having a logical input coupled to said second high voltage domain node and a logical output coupled to said first high voltage domain node, wherein said fourth inverter is a static CMOS inverter which drives said second voltage at the input of said fourth inverter to said third voltage at the output of said fourth inverter and drives said third voltage at the input of said fourth inverter to said second voltage at the output of said fourth inverter;
said voltage buffer being electrically coupled to the first high voltage domain node and the second high voltage domain node and outputting either the second voltage or the third voltage, said third voltage being higher than said second voltage.

2. (canceled)

3. The voltage level translating circuit of claim 1 wherein the voltage buffer further comprises:
a first voltage buffer portion having a constant logical input at the second voltage and a logical output substantially at either the first voltage or the third voltage; and
a second voltage buffer portion having a constant logical input at the second voltage and a logical output substantially at either the third voltage or the first voltage.

4. The voltage level translating circuit of claim 3 wherein the first voltage buffer portion further comprises:
a first n-type field effect transistor (NFET); and
a first p-type field effect transistor (PFET);
wherein the gate of the first NFET and the gate of the first PFET are at the second voltage, the source of the first NFET is electrically connected to the output of the first inverter, and the drain of the first NFET and the drain of the first PFET are electrically connected.

5. The voltage level translating circuit of claim 4 wherein the second voltage buffer portion further comprises:
a second n-type field effect transistor (NFET); and
a second p-type field effect transistor (PFET);
wherein the gate of the second NFET and the gate of the second PFET are at the second voltage, the source of the second NFET is electrically connected to the output of the second inverter, and the drain of the second NFET and the drain of the second PFET are electrically connected.

6. The voltage level translating circuit of claim 5 wherein the source of the first PFET, the logical input of the third inverter, and the logical output of the fourth inverter are electrically connected.

7. The voltage level translating circuit of claim 6 wherein the source of the second PFET, the logical input of the fourth inverter, the logical output of the third inverter, and the logical input of the buffer are electrically connected.

8. A design structure embodied in a machine readable storage medium for designing, manufacturing, or testing a design, the design structure comprising:
a voltage buffer connected to a low voltage domain and a high voltage domain wherein a high voltage of the low voltage domain serves as a low voltage of the high voltage domain;
wherein the low voltage domain further comprises:
a first inverter having a first logical input and outputting either a first voltage or a second voltage; and
a second inverter having a second logical input and outputting either the first voltage or the second voltage;
wherein the second logical input is the logical inverse of the first logical input, and wherein the second voltage is larger than the first voltage, and is the high voltage of the low voltage domain;
and wherein the high voltage domain comprises a latch formed by:
a third inverter having a logical input coupled to a first high voltage domain node and a logical output coupled to a second high voltage domain node, wherein said third inverter is a static CMOS inverter which drives said second voltage at the input of said third inverter to a third voltage at the output of said third inverter and drives said third voltage at the input of said third inverter to said second voltage at the output of said third inverter, and
a fourth inverter having a logical input coupled to said second high voltage domain node and a logical output coupled to said first high voltage domain node, wherein said fourth inverter is a static CMOS inverter which drives said second voltage at the input of said fourth inverter to said third voltage at the output of said fourth inverter and drives said third voltage at the input of said fourth inverter to said second voltage at the output of said fourth inverter;
said voltage buffer being electrically coupled to the first high voltage domain node and the second high voltage domain node and outputting either the second voltage or the third voltage, said third voltage being higher than said second voltage.

9. (canceled)

10. The design structure of claim 8 wherein the voltage buffer further comprises:
a first voltage buffer portion having a constant logical input at the second voltage and a logical output substantially at either the first voltage or the third voltage; and
a second voltage buffer portion having a constant logical input at the second voltage and a logical output substantially at either the third voltage or the first voltage.

11. The design structure of claim 10 wherein the first voltage buffer portion further comprises:
a first n-type field effect transistor (NFET); and
a first p-type field effect transistor (PFET);
wherein the gate of the first NFET and the gate of the first PFET are at the second voltage, the source of the first NFET is electrically connected to the output of the first inverter, and the drain of the first NFET and the drain of the first PFET are electrically connected.

12. The design structure of claim 11 wherein the second voltage buffer portion further comprises:
a second n-type field effect transistor (NFET); and
a second p-type field effect transistor (PFET);
wherein the gate of the second NFET and the gate of the second PFET are at the second voltage, the source of the second NFET is electrically connected to the output of the second inverter, and the drain of the second NFET and the drain of the second PFET are electrically connected.

13. The design structure of claim 12 wherein the source of the first PFET, the logical input of the third inverter, the logical output of the fourth inverter are electrically connected, and wherein the source of the second PFET, the logical input of the fourth inverter, the logical output of the third inverter, and the logical input of the buffer are electrically connected.

14. The design structure of claim 8, wherein the design structure comprises a netlist, which describes the circuit.

15. The design structure of claim 8, wherein the design structure resides on storage medium as a data format used for the exchange of layout data of integrated circuits.

16. The design structure of claim 8, wherein the design structure includes at least one of test data files, characterization data, verification data, or design specifications.

17. A method of manufacturing a voltage level translating circuit comprising:
electrically connecting the gate and the drain of a first n-type field effect transistor (NFET) to the respective gate and drain of a first p-type field effect transistor (PFET);
electrically connecting the gate and the drain of a second NFET to the respective gate and drain of a second PFET;
electrically connecting the connected gates of the first NFET and of the first PFET to the connected gates of the second NFET and of the second PFET;
electrically connecting the source of the first NFET to the output of a first inverter;
electrically connecting the source of the second NFET to the output of a second inverter;
electrically connecting the source of the first PFET to the input of a third inverter and to the output of a fourth inverter;
electrically connecting the source of the second PFET to the output of the third inverter and to the input of the fourth inverter; and
electrically connecting the output of the third inverter to the input of a buffer
wherein said first inverter is configured to output either a first voltage or a second voltage, and
wherein said second inverter is configured to output either the second voltage or the first voltage, and wherein said third inverter and said fourth inverter are static CMOS inverters forming a latch, said third inverter being configured to utilize a logical input either at the second voltage or a third voltage and to output a logical output either at the third voltage or the second voltage, and said fourth inverter being configured to utilize a logical input either at the third voltage or the second voltage and to output a logical output either at the second voltage or the third voltage, the third voltage being higher than the second voltage, the second voltage being higher than the first voltage.

18. The method of claim 17 further comprising:
allowing for a first logical signal to be an input to the first inverter, and;
allowing for the inverse of the first logical signal to be an input to the second inverter.

19. (canceled)

20. The method of claim 17, wherein the first inverter and the second inverter are configured to operate in a low voltage domain, and wherein the third inverter, the fourth inverter, and the buffer are configured to operate in a high voltage domain, the buffer is configured to output a voltage output supply, and wherein the first NFET, the first PFET, the second NFET, and the second PFET are configured to operate as a voltage buffer, and wherein the high voltage of the low voltage domain is the second voltage and is configured to also serve as a low voltage of the high voltage domain.
